(19) United States
(12) Patent Application Publication
(10) Pub. No.: US 2026/0099703 A1
(43) Pub. Date: Apr. 9, 2026

(54) VARIABLE-BIT ADAPTIVE SENSING CIRCUIT SYSTEM IN ANALOG NEUROMORPHIC SYSTEMS

(71) Applicant: KOREA UNIVERSITY RESEARCH AND BUSINESS FOUNDATION, Seoul (KR)

(72) Inventors: Hyung Min LEE, Seoul (KR); Min Seong UM, Seoul (KR); Min Il KANG, Seoul (KR)

(21) Appl. No.: 19/185,582

(22) Filed: Apr. 22, 2025

(30) Foreign Application Priority Data
Oct. 7, 2024 (KR) 10-2024-0135318

(51) Int. Cl. G06N 3/065; G01R 31/3163

(52) U.S. Cl. CPC G06N 3/065; G01R 31/3163

(57) ABSTRACT

A variable-bit adaptive sensing circuit system in an analog neuromorphic system is disclosed. In an analog neuromorphic system including a synapse array, the circuit system for sensing the synapse array comprises: a sensing part circuit configured to sense output currents of synapse devices in each column of the synapse array in response to an operation signal; an error detection circuit configured to detect errors based on the column-wise output currents of the synapse devices and determine an operation start reference; and an analog-to-digital conversion circuit configured to integrate the synapse device current based on the operation start reference, convert the integrated current into a voltage value, and output a corresponding digital value.

### CROSS-REFERENCE TO RELATED APPLICATION

This application claims the benefit of priority under 35 U.S.C. §119(a) to Korean Patent Application No. 10-2024-0135318, filed on October 7, 2024, with the Korean Intellectual Property Office the entire contents of which is incorporated herein by reference.

### BACKGROUND

### a Technical Field

The present disclosure relates to a variable-bit adaptive sensing circuit system in analog neuromorphic systems.

### b Background Art

Neuromorphic devices aim to emulate the neural networks of the human brain, thereby dramatically enhancing the performance of artificial intelligence (AI) and deep learning systems. These devices offer superior power efficiency and parallel data processing capabilities, overcoming the limitations of traditional Von Neumann architectures. In particular, neuromorphic devices are capable of performing multiply-accumulate (MAC) operations in parallel, enabling high-speed processing of matrix-vector multiplication (MVM), which is essential in deep learning models. This parallel computing capability provides a significant advantage for neuromorphic systems in performing AI and deep learning tasks.

However, the conductance (or resistance) range of neuromorphic devices varies widely, making accurate sensing a critical challenge. In particular, the Readout Integrated Circuit (ROIC) used in neuromorphic systems plays a key role in measuring the conductance of each synaptic device and handling data processing. The accurate sensing capability of the ROIC is directly linked to the overall performance of the system, and any errors can negatively affect data reliability and the efficiency of the learning process. For instance, failure to accurately read and write data from analog synaptic devices with varying conductance levels may result in reduced learning speed and accuracy in AI systems.

Therefore, to enhance the performance of neuromorphic systems and the overall ROIC, it is necessary to implement methods that minimize sensing errors occurring in each column.

### SUMMARY OF THE DISCLOSURE

The present disclosure is directed to providing a variable-bit adaptive sensing circuit system in an analog neuromorphic system.

In addition, the present disclosure provides a variable-bit adaptive sensing circuit system for an analog neuromorphic system that can adaptively detect and minimize errors occurring during variable conductance sensing, and that enables efficient energy management during training and inference phases by adjusting the number of bits.

Furthermore, the present disclosure provides a variable-bit adaptive sensing circuit system in an analog neuromorphic system that not only minimizes errors through adaptive error detection in the variable conductance sensing process, but also ensures accurate sensing throughout the entire readout IC, thereby improving the reliability and accuracy of the overall system beyond the neuromorphic system alone.

Moreover, the present disclosure provides a variable-bit adaptive sensing circuit system in an analog neuromorphic system that enables fine-grained weight tuning and precise data processing during training, and optimized real-time data processing during inference through an analog-to-digital converter with variable bit resolution tailored to the characteristics of training and inference.

Through the above, the present disclosure offers a variable-bit adaptive sensing circuit system in an analog neuromorphic system capable of reducing power consumption, improving real-time response performance, and maximizing system efficiency by implementing optimal performance tailored to system requirements using analog-to-digital converters of various bit resolutions, thereby enhancing applicability across a wide range of use cases.

According to one aspect of the present disclosure, a variable-bit adaptive sensing circuit system in an analog neuromorphic system is provided.

According to an embodiment of the present disclosure, there is provided a circuit system for sensing a synapse array in an analog neuromorphic system including the synapse array, the circuit system comprising: a sensing part circuit configured to sense output currents of synapse devices in each column of the synapse array in response to an operation signal applied to the synapse array; an error detection circuit configured to detect errors based on the output currents of the synapse devices in each column and determine an operation start reference; and an analog-to-digital conversion circuit configured to integrate the current of the synapse devices based on the operation start reference, convert the integrated current into a voltage value, and output a digital value.

The sensing part circuit comprises an M₀ transistor connected to an output terminal of the synapse device, wherein the synapse device is set to a maximum resistance value; a comparator configured to provide negative feedback of the output current of the synapse device, wherein an output of the comparator is applied as a control voltage (V_{GG}) to a gate node of the M₀ transistor, and a positive (+) input terminal of the comparator receives a reference voltage (V_{REFS}); and an M_{G} transistor having a source node to which the reference voltage (V_{REFS}) is applied and a gate node to which an operation reference voltage (V_{GR}) is applied, wherein a drain node of the M₀ transistor and a drain node of the M_{G} transistor are connected to drain nodes of a first and a second current mirror transistor, respectively, the gate nodes of the first and second current mirror transistors are connected to each other such that the operation reference voltage (V_{GR}) is generated based on the maximum resistance value of the synapse device.

The error detection circuit comprises a comparison circuit configured to receive an output voltage (V_{S}) of the synapse device, a reference voltage (V_{REFS}) used for controlling the output current of the synapse device, a control voltage (V_{GG}), and an operation reference voltage (V_{GR}), and to detect an error based on the input signals; an RS latch circuit located downstream of the comparison circuit, configured to receive a comparison result between the output voltage (V_{S}) and the reference voltage (V_{REFS}) as an R input, and a comparison result between the control voltage (V_{GG}) and the operation reference voltage (V_{GR}) as an S input; and a long pulse detector (LPD) circuit located downstream of the RS latch circuit, configured to determine the operation start reference by detecting the longest error pulse based on a change in a Q value of the RS latch circuit.

The circuit system may further comprise a bias control circuit configured to control an output bit based on a reference current, wherein the analog-to-digital conversion circuit is configured to output a digital value corresponding to the integrated voltage value according to the output bit.

The analog-to-digital conversion circuit comprises a slope analog-to-digital converter.

### BRIEF DESCRIPTION OF DRAWINGS

FIG. 1 is a diagram illustrating the overall structure of an analog neuromorphic system according to an embodiment of the present disclosure.

FIG. 2 is a diagram illustrating sensing errors in a sensing part circuit according to an embodiment of the present disclosure.

FIG. 3 is a diagram illustrating an operation reference circuit unit according to an embodiment of the present disclosure.

FIG. 4 is a diagram illustrating an error detection circuit according to an embodiment of the present disclosure.

FIG. 5 is a detailed circuit diagram of the analog neuromorphic system according to an embodiment of the present disclosure.

FIG. 6 is a diagram illustrating example waveforms of the error detection operation according to an embodiment of the present disclosure.

FIG. 7 is a detailed circuit diagram of the analog conversion circuit according to an embodiment of the present disclosure.

FIG. 8 is a diagram illustrating simulation waveforms of the overall operation of the analog neuromorphic architecture according to an embodiment of the present disclosure.

### DETAILED DESCRIPTION

Singular forms used in this specification include plural forms unless the context clearly indicates otherwise. In the specification, the term “configured”, “include”, or the like should not be construed as necessarily including several components or several steps described herein, in which some of the components or steps may not be included or additional components or steps may be further included. Further, the terms “~ unit”, “module”, and the like mean a unit for processing at least one function or operation and may be implemented by hardware or software or by a combination of hardware and software.

Hereinafter, the embodiments of the present disclosure will be described in detail with reference to the accompanying drawings.

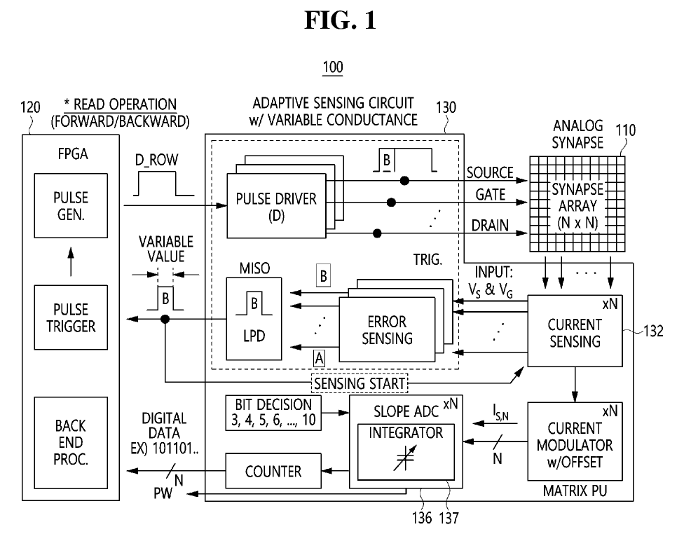

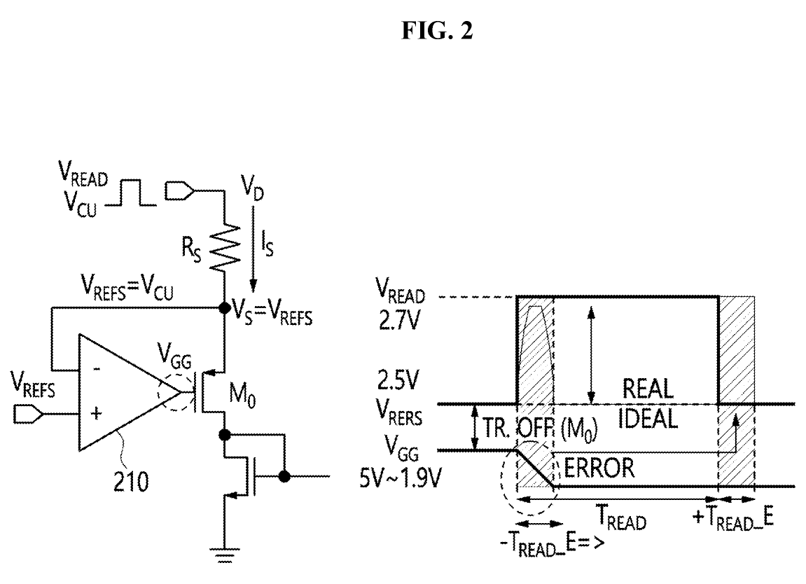

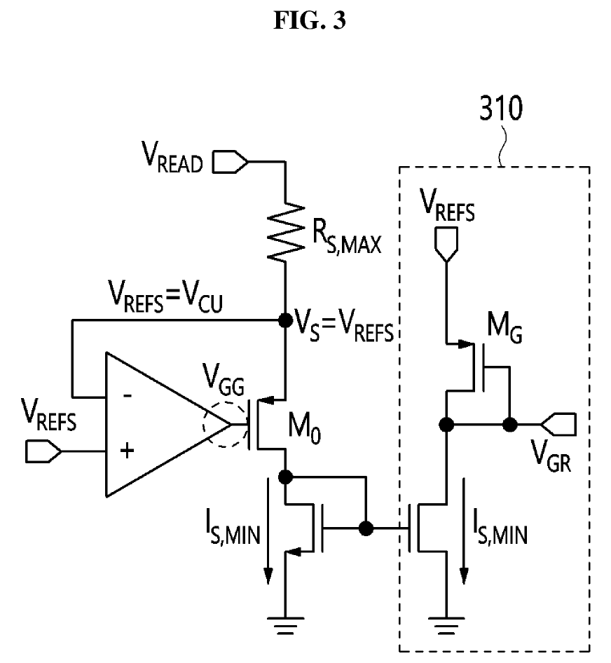

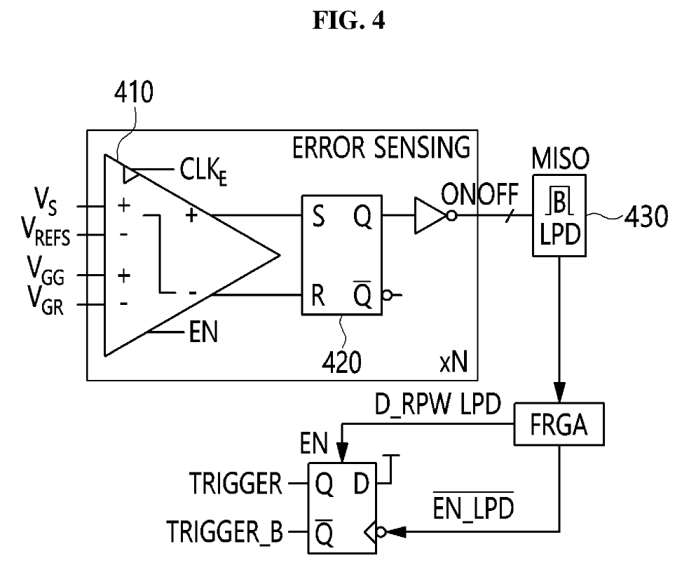

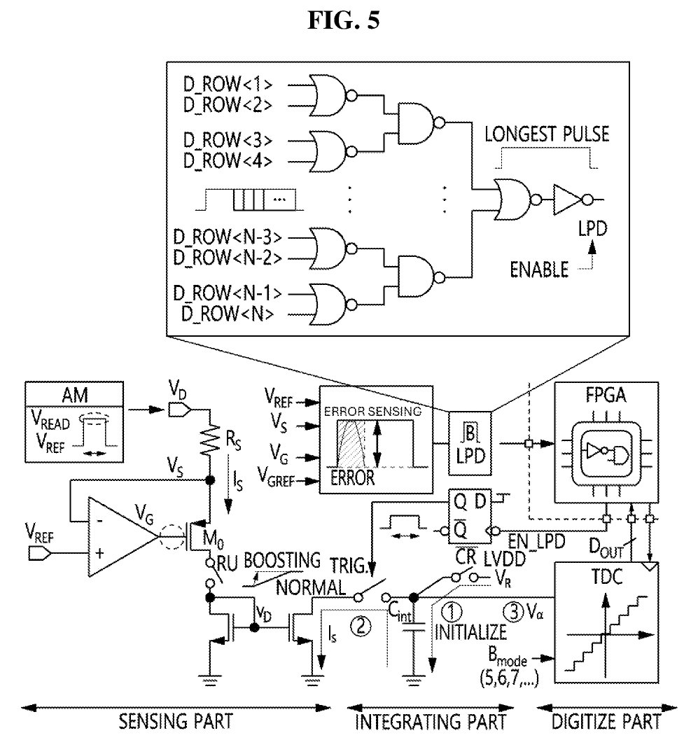

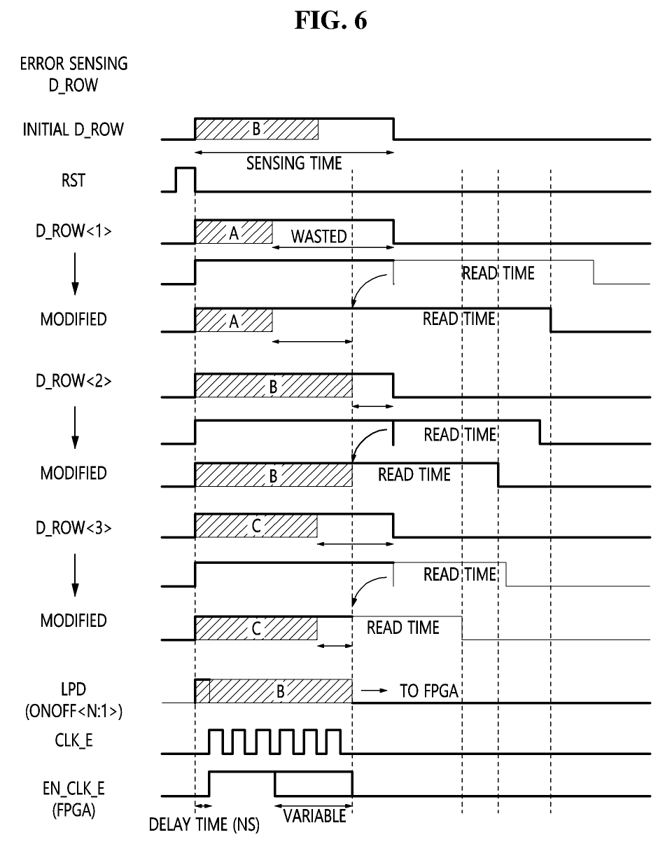

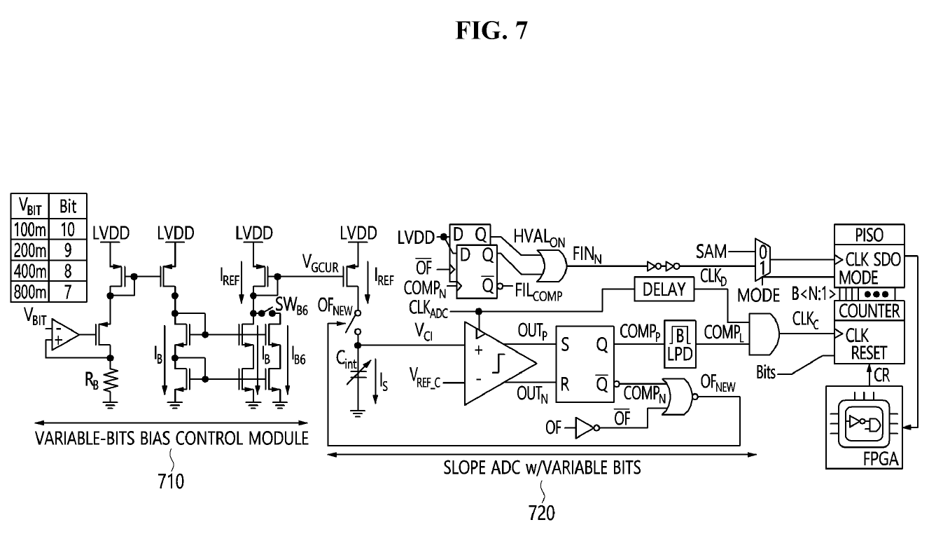

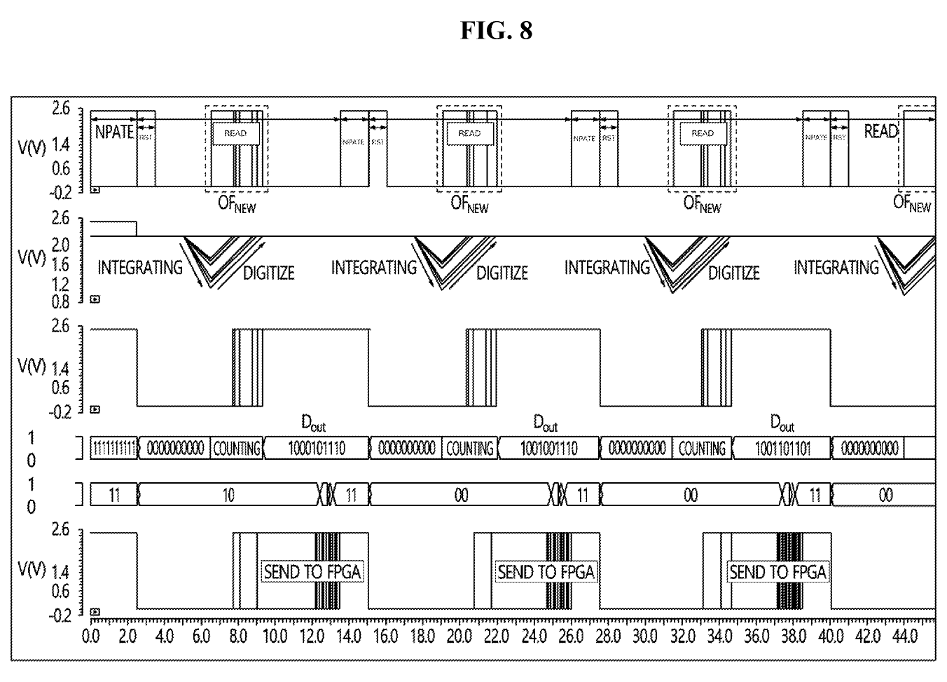

FIG. 1 is a diagram illustrating the overall structure of an analog neuromorphic system according to an embodiment of the present disclosure, FIG. 2 is a diagram illustrating sensing errors in a sensing part circuit according to an embodiment of the present disclosure, FIG. 3 is a diagram illustrating an operation reference circuit unit according to an embodiment of the present disclosure, FIG. 4 is a diagram illustrating an error detection circuit according to an embodiment of the present disclosure, FIG. 5 is a detailed circuit diagram of the analog neuromorphic system according to an embodiment of the present disclosure, FIG. 6 is a diagram illustrating example waveforms of the error detection operation according to an embodiment of the present disclosure, FIG. 7 is a detailed circuit diagram of the analog conversion circuit according to an embodiment of the present disclosure, and FIG. 8 is a diagram illustrating simulation waveforms of the overall operation of the analog neuromorphic architecture according to an embodiment of the present disclosure.

Referring to FIG. 1, an analog neuromorphic system (100) according to an embodiment of the present disclosure includes a synapse array (110), an FPGA circuit unit (120), and an adaptive sensing circuit unit (130).

The synapse array (110) may include synapse devices arranged in an N × N matrix. Here, N is a natural number. Each synapse device is capable of adjusting weights and storing or transmitting signals by utilizing variable resistance or conductance.

For the sake of clarity and ease of explanation, it is assumed that the synapse devices are ECRAM synapse devices and ReRAM synapse devices, and the description will be provided based on this assumption. In addition, it is assumed that each synapse device in the synapse array is implemented using a transistor. Accordingly, each synapse device may include a gate node, a drain node, and a source node.

The FPGA circuit unit (120) may include a signal generation circuit unit, a backend circuit unit, and the like.

The signal generation circuit unit may generate waveforms corresponding to update or read operations, and the backend circuit unit is configured to receive and process output values from the analog-to-digital conversion circuit unit (136).

The waveform generated by the FPGA circuit unit (120) is transmitted to a pulse driver in the adaptive sensing circuit unit (130), and the pulse driver may generate a voltage pulse based on the waveform from the FPGA circuit unit (120) and deliver it to the synapse device.

As shown in FIG. 1, the pulse driver may apply individual voltage pulses to the gate node, drain node, and source node of each synapse device.

The output current (I_{S,N}) of the synapse device varies depending on the length of the voltage pulse applied to the synapse device and the weight (conductance) of the synapse device.

The adaptive sensing circuit unit (130) senses the output current of synapse devices in each column of the synapse array in response to an operation signal applied to the synapse array, detects errors, determines an operation start reference, and senses the current of the synapse devices based on the operation start reference to output a digital value.

The adaptive sensing circuit unit (130) comprises a sensing part circuit unit (132), an error detection circuit unit (134), and an analog-to-digital conversion circuit unit (136).

The sensing part circuit unit (132) is configured to measure current variations in the synapse array to which a voltage is applied according to a control signal, serving as a means for reading the state of the synapse devices.

In the case of synapse devices such as ECRAM and ReRAM, which have a wide weight (resistance) range, the sensing part circuit unit may include a current control circuit unit in order to cover and manage the entire range.

Referring to FIGS. 2 and 3, the configuration of the sensing part circuit unit (132) will now be described.

The sensing part circuit unit (132) may include a current control circuit unit (M₀) configured to control the current of the synapse device. Here, the current control circuit unit (M₀) may be a PMOS transistor.

A source node of the current control circuit unit (M₀) is connected to an output node (V_{S}) of the synapse device, and a gate node thereof is connected to an output terminal of a comparator (210).

The comparator (210) operates in negative feedback, with its negative (−) input terminal connected to the output node (V_{S}) of the synapse device, and its positive (+) input terminal configured to receive a reference voltage (V_{REFS}). The output of the comparator (210) may be applied as a control voltage (V_{GG}) to the gate node of the current control circuit unit (M₀).

The sensing part circuit unit (132) may further include a current mirror circuit unit (M_{T1}), which may be an NMOS transistor. That is, a drain node of the current control circuit unit (Mₑ) may be connected to a drain node of the current mirror circuit unit (M_{T1}).

As shown in FIG. 2, the comparator (210) functions as a negative feedback circuit, in which the output node (V_{S}) of the synapse device is connected to the negative (−) input terminal of the comparator (210), and the output of the comparator (210) is connected to the gate node of the current control circuit unit (Mₑ). That is, due to the negative feedback of the comparator (210), the output voltage (V_{S}) at the output node of the synapse device becomes equal to the reference voltage (V_{REFS}).

An error may occur when the output voltage (V_{S}) at the output node of the synapse device does not match the reference voltage (V_{REFS}) due to the resistance (R_{S}) value of the synapse device.

The current control circuit unit (M₀) senses the output current (I_{S}) of the synapse device, and the output (V_{GG}) of the comparator (210) is adjusted according to the output current of the synapse device. However, due to the error at the output node (V_{S}) of the synapse device and the time required for the output voltage (V_{GG}) of the comparator (210) to converge to the correct value, errors may occur simultaneously.

In addition, when the resistance value of the synapse device is low, the output current (I_{S}) of the synapse device becomes excessively large, causing a momentary increase in the voltage at the output node (V_{S}) of the synapse device. Conversely, when the resistance value of the synapse device is high, the output current (I_{S}) of the synapse device becomes very small, causing the current control circuit unit (M₀) to take longer to sense the output current. As a result, the output voltage (V_{GG}) of the comparator (210) takes more time to converge to the correct value.

That is, since the type of error and the time required to return to a stable state vary depending on the resistance value of the synapse device, a circuit capable of adaptively detecting errors is required to prevent errors caused by the diverse conductance levels of the synapse devices.

To address this, according to an embodiment of the present disclosure, the adaptive sensing circuit unit (130) may further include an operation reference circuit unit (310) and an error detection circuit unit (134).

The operation reference circuit unit (310) may generate an operation reference voltage for determining the operation start reference based on the maximum resistance value (R_{S,MAX}) of the synapse device.

The operation reference circuit unit (310) is illustrated in FIG. 3.

As shown in FIG. 3, the operation reference circuit unit (310) may set a reference threshold by generating an operation reference voltage (V_{GR}) based on the maximum resistance value (R_{S,MAX}) of the synapse device (conductance), since the worst-case error occurs when the output (V_{GG}) of the comparator (210) reaches its highest value, which corresponds to the maximum resistance value (R_{S,MAX}).

To this end, the operation reference circuit unit (310) includes an M_{G} transistor, in which the reference voltage (V_{REFS}) is applied to a source node, and the operation reference voltage (V_{GR}) is applied to a gate node. A drain node of the M_{G} transistor and a drain node of the M₀ transistor are connected to drain nodes of a first and a second current mirror transistor, respectively, and gate nodes of the first and second current mirror transistors are connected to each other, such that the operation reference voltage (V_{GR)} may be generated based on the maximum resistance value.

The error detection circuit unit (134) may detect an error using the operation reference voltage (V_{GR}) and determine whether to proceed with the operation.

FIG. 4 illustrates the detailed configuration of the error detection circuit unit (134).

The error detection circuit unit (134) comprises a comparison circuit unit (410) and an RS latch circuit unit (420).

The comparison circuit unit (410) may receive the output voltage (V_{S}) of the synapse device, the reference voltage (V_{REFS}) used to control the output current of the synapse device, the control voltage (V_{GG}), and the operation reference voltage (V_{GR}), and may detect an error based on these inputs.

For example, the comparison circuit unit (410) may receive the operation reference voltage (V_{GR}) as a second negative (−) input and the control voltage (V_{GG}) as a second positive (+) input. Accordingly, the comparison circuit unit (410) may determine that an error has occurred if the control voltage (V_{GG}) is higher than the operation reference voltage (V_{GR) and} may refrain from performing the read operation in such a case. In contrast, if the control voltage (V_{GG}) is lower than the operation reference voltage (V_{GR}), the comparison circuit unit (410) may determine that the read operation is nearly error-free and may output a signal for current integration.

In addition, although the output voltage (V_{S}) of the synapse device is intended to be regulated to match the reference voltage through feedback, it may momentarily rise depending on the resistance value of the synapse device. Therefore, the comparison circuit unit (410) may compare the output voltage (V_{S}) of the synapse device with the reference voltage (V_{REFS})to determine whether they are equal.

The comparison circuit unit (410) may determine that there is no error in the read operation if the control voltage (V_{GG}) is lower than the operation reference voltage (V_{GR}) and the output voltage (V_{S}) of the synapse device is equal to the reference voltage (V_{REFS}), and may control the system to proceed with the read operation accordingly.

The two outputs of the comparison circuit unit (410) may be input to the RS latch circuit unit (420).

For example, the comparison circuit unit (410) may receive the output voltage (V_{S}) of the synapse device as a first positive (+) input and the reference voltage (V_{REFS}) as a first negative (−) input, compare the two, and output the result through a negative output terminal to the R terminal of the RS latch circuit unit (420).

In addition, the comparison circuit unit (410) may receive the control voltage (V_{GG}) as a second positive (+) input and the operation reference voltage (V_{GR}) as a second negative (−) input, compare the two, and output the result through a positive output terminal to the S terminal of the RS latch circuit unit (420).

Since the error occurrence time may vary for each column, in an embodiment of the present disclosure, the longest error pulse can be detected through a long pulse detector (LPD) circuit unit (136).

A long pulse detector circuit unit (430) may be located downstream of the error detection circuit unit (134). More specifically, the long pulse detector circuit unit (430) may be positioned downstream of the RS latch circuit unit (420), read the Q value of the RS latch circuit unit (420) to detect the duration of the error pulse, and output an operation reference pulse based on the longest detected error pulse.

Referring to FIG. 6, for example, it is assumed that A, B, and C represent the error durations of the first, second, and third columns, respectively. In this case, since the error duration of B is the longest, the long pulse detector circuit unit (430) may output the B pulse as the operation reference pulse.

Therefore, based on the output of the long pulse detector circuit unit (430), i.e., the operation reference pulse, the integration circuit unit (137) and the analog-to-digital conversion circuit unit (136) may perform the read operation. The detailed structure of the long pulse detector circuit unit (430) is illustrated in FIG. 5.

After an error is detected by the error detection circuit unit (134), the integration circuit unit (137) may operate based on the operation reference pulse to integrate the sensed current during the actual read time and generate a voltage value (V_{CI}). That is, the output of the long pulse detector circuit unit (430) is transmitted to the FPGA circuit unit (120), and the integration circuit unit (137) and the analog conversion circuit unit (136) may be operated based on the operation reference pulse (error pulse) generated by the FPGA circuit unit (120).

The voltage value (V_{CI}) output from the integration circuit unit (137) may be delivered to the analog-to-digital conversion circuit unit (136) and converted into a digital value. The analog-to-digital conversion circuit unit (136) may be a slope analog-to-digital converter.

According to an embodiment of the present disclosure, the integration circuit unit (137) may be included in the analog-to-digital conversion circuit unit (136).

FIG. 7 is a diagram illustrating a detailed circuit diagram of the analog-to-digital conversion circuit unit (136).

Referring to FIG. 7, the analog-to-digital conversion circuit unit (136) includes a bias control circuit unit (710), which controls the output bit based on a reference current, and a slope analog-to-digital conversion unit (720).

The bias control circuit unit (710) may turn a switch (SW_{B6}) on or off and adjust an operation bit voltage (V_{BIT}) according to a reference current (I_{REF}), thereby controlling the amount of the reference current (I_{REF}) to match the corresponding bit level.

To increase the output bit resolution, the operation bit voltage (V_{BIT}) may be decreased; conversely, to decrease the output bit resolution, the operation bit voltage (VBIT) may be increased, thereby adjusting the resolution of the slope analog-to-digital conversion unit (720).

The switch (SW_{B6}) is used to extend the bit range and allows the current to be reduced in 4-bit steps at a time. After the output bit(resolution) is adjusted by controlling the operation bit voltage (V_{BIT}), the slope analog-to-digital conversion unit (720) may control the bits by turning a counter and a parallel-in serial-out (PISO) shift register on or off.

The slope analog-to-digital conversion unit (720) may adjust its output resolution by controlling the logic on/off states of a counter and a parallel-in serial-out (PISO) shift register based on the output of the bias control circuit unit (710).

The slope analog-to-digital conversion unit (720), used across multiple channels and columns, can share circuitry and logic such as the counter and the bias control circuit unit (710), providing significant advantages in terms of power consumption and area efficiency, making it highly beneficial.

FIG. 8 is a diagram illustrating overall operation simulation waveforms according to an embodiment of the present disclosure. FIG. 8 shows simulation results based on a 32 ×32synapse array, in which update and read operations are repeated. After updating the synapse array, matrix operations (read operations) may be performed. In the read operation, all nodes are reset, and errors are detected for each column through the error detection circuit unit (134). Then, based on the operation reference pulse output by the long pulse detector circuit unit (430), the integration circuit unit (137) operates to integrate the sensed current. Since the integrated result from the integration circuit unit (137) varies for each column, different output results are generated. Depending on the number of bits, the output value (Dout) may be produced according to the output bit level, matched to the reference current (I_{REF}). The output digital values may be sequentially transmitted per column through a parallel-in serial-out (PISO) shift register. More specifically, the result values of the counter are delivered and stored in each PISO shift register through a FIN_{N} signal. Once all operations are completed, the final output values (Dout) stored in the column-wise PISO shift registers may be output to the FPGA circuit unit (120).

The device and method according to the embodiments of the present disclosure may be implemented in a program that can be executed by various computers and may be recorded on computer-readable media. The computer-readable media may include program commands, data files, and data structures individually or in combinations thereof. The program commands that are recorded on a computer-readable media may be those specifically designed and configured for the present disclosure or may be those known to those engaged in the computer software field and thus available. The computer-readable recording media include magnetic media such as hard disks, floppy disks, and magnetic media such as a magnetic tape, optical media such as CD-ROMs and DVDs, magneto-optical media such as floptical disks, and hardware devices specifically configured to store and execute program commands, such as ROM, RAM, and flash memory. The program commands include not only machine language codes compiled by a compiler, but also high-level language code that can be executed by a computer using an interpreter, etc.

The hardware device may be configured to operate as one or more software modules to perform the operation of the present disclosure, and vice versa.

The present disclosure was described above focusing on the embodiments thereof. It would be understood by those skilled in the art that the present disclosure may be implemented in a modified form without departing from the scope of the present disclosure. Therefore, the disclosed embodiments should be considered in terms of explaining, not limiting. The scope of the present disclosure is shown in the claims, not in the above description, and all differences within an equivalent range should be construed as being included in the present disclosure.

What is claimed is:

1. A circuit system for sensing a synapse array in an analog neuromorphic system including the synapse array, the circuit system comprising:
a sensing part circuit configured to sense output currents of synapse devices in each column of the synapse array in response to a signal applied to operate the synapse array;
an error detection circuit configured to detect an error based on the output currents of the synapse devices in each column and to determine an operation start reference; and
an analog-to-digital conversion circuit configured to integrate the output currents of the synapse devices based on the operation start reference, convert the integrated currents into voltage values, and output the voltage values as digital values.

2. A circuit system for sensing a synapse array in an analog neuromorphic system including the synapse array of claim 1,
wherein the sensing part circuit comprises:
an M₀ transistor connected to an output terminal of the synapse device, wherein the synapse device is set to a maximum resistance value;
a comparator configured to provide negative feedback of the output current of the synapse device, wherein an output of the comparator is applied as a control voltage (V_{GG}) to a gate node of the M₀ transistor, and a positive (+) input terminal of the comparator receives a reference voltage (V_{REFS}); and
an M_{G} transistor having a source node to which the reference voltage (V_{REFS}) is applied and a gate node to which an operation reference voltage (V_{GR}) is applied,
wherein a drain node of the M₀ transistor and a drain node of the M_{G} transistor are connected to drain nodes of a first and a second current mirror transistor, respectively, the gate nodes of the first and second current mirror transistors are connected to each other such that the operation reference voltage (V_{GR}) is generated based on the maximum resistance value of the synapse device.

3. A circuit system for sensing a synapse array in an analog neuromorphic system including the synapse array of claim 1,
wherein the error detection circuit comprises:
a comparison circuit configured to receive an output voltage (V_{S}) of the synapse device, a reference voltage (V_{REFS}) used for controlling the output current of the synapse device, a control voltage (V_{GG}), and an operation reference voltage (V_{GR}), and to detect an error based on the input signals;
an RS latch circuit located downstream of the comparison circuit, configured to receive a comparison result between the output voltage (V_{S}) and the reference voltage (V_{REFS}) as an R input, and a comparison result between the control voltage (V_{GG}) and the operation reference voltage (V_{GR}) as an S input; and
a long pulse detector (LPD) circuit located downstream of the RS latch circuit, configured to determine the operation start reference by detecting the longest error pulse based on a change in a Q value of the RS latch circuit.

4. A circuit system for sensing a synapse array in an analog neuromorphic system including the synapse array of claim 1,
further comprising a bias control circuit configured to control an output bit based on a reference current,
wherein the analog-to-digital conversion circuit is configured to output a digital value corresponding to the integrated voltage value in accordance with the output bit.

5. A circuit system for sensing a synapse array in an analog neuromorphic system including the synapse array of claim 1,
wherein the analog-to-digital conversion circuit comprises a slope analog-to-digital converter.
